(19) United States
(12) Patent Application Publication
(10) Pub. No.: US 2008/0203412 A1
(43) Pub. Date: Aug. 28, 2008

(54) LED assembly with molded glass lens

(75) Inventors: San-Woei Shyu, Taipei (TW); Ching-Yuan Lin, Taipei (TW); Chien-Yi Huang, Taipei (TW)

Correspondence Address: TROXELL LAW OFFICE PLLC, SUITE 1404, 5205 LEESBURG PIKE, FALLS CHURCH, VA, 22041, US

(73) Assignee: E-PIN OPTICAL INDUSTRY CO., LTD.

(21) Appl. No.: 11/711,890

(22) Filed: Feb. 28, 2007

(51) Int. Cl. H01L 33/00

(52) U.S. Cl. 257/98; 257/E33.068

(57) ABSTRACT

A LED assembly with a molded glass lens includes a base, at least one LED chip and a cover lens. The LED assembly feature on that the cover lens consists of a molded glass lens and a transparent resin layer. A molded glass lens is covered on a loading surface of the base and then liquid transparent resin is filled into space between an inner surface of the molded glass lens and the loading surface through preset filling holes to coat the LED chip completely. After hardening, the transparent resin integrated with the molded glass lens so as to replace conventional cover lens made from transparent resin. Therefore, not only thermal resistance, weather resistance, discoloration resistance, and mechanical strength of the LED assembly are increased, but the brightness and light-emitting efficiency of the LED assembly are also improved.

### BACKGROUND OF THE INVENTION

The present invention relates to a LED assembly, especially to a LED assembly with a molded glass lens replacing a conventional cover lens made from transparent resin.

Traditional LED assemblies have various package structures. The most common structure is composed of a base, at least one LED chip and a cover lens. Moreover, heat spreaders or heat sinks are added for heat dissipation according to user's needs. There is no limit on structure and material of the base. Generally, it is made from insulating; material such as plastic with electrodes such as pins for connecting with an external power source. Moreover, a loading surface for disposition of the LED chip is on top of the base and the LED chip is electrically connected with positive and negative electrodes to get power supply so as to drive the LED chip emit light. There are various designs of electrical connection such as by conducting wires or conducting strips to connect between the electrodes of the LED chip and the pins of the base. The cover lens made from transparent resin is disposed on the loading surface of the base and encloses the LED chip to form a complete package. However, the cover lens of conventional LED assemblies is made from transparent resin such as epoxy and silicon. The thermal resistance, weather resistance, discoloration resistance (UV resistance), and mechanical strength (wear resistance) are restricted. Thus the applications of the LED assemblies have been affected. The resin can't achieve characters of the molded glass lens. For example, for a high-power high-brightness white-light LED, it has higher temperature when it emits light. The softening temperature of general resin is lower than that of the molded glass lens so that the lens made from resin is easy to be affected by the high temperature. There is a need to add heat dissipation devices and the package structure becomes more complicated. Furthermore, the refraction and transmittance of the resin lens are both lower than the molded glass lens. This also has negative effect on brightness and efficiency of the LED assemblies.

### SUMMARY OF THE INVENTION

Therefore it is a primary object of the present invention to provide a LED assembly with molded glass lens that includes a base, at least one LED chip, and a cover lens to form a package structure. The cover lens consists of a molded glass lens and a transparent resin layer. By means of preset filling holes of a molded glass lens covered on a loading surface of the base, liquid transparent resin material is filled in space between an inner surface of the molded glass lens and the loading surface so as to coat the LED chip completely. After hardening, the transparent resin is integrated with the molded glass lens. Thus the thermal resistance, weather resistance, discoloration resistance and mechanical strength of the LED assembly 1 are effectively improved. The brightness and light-emitting efficiency are also improved.

It is another object of the present invention to provide a LED assembly with molded glass lens. The surface types and different optical parameters of inner/outer (or upper/lower) optical surfaces can be varied according to requirements of design. For example, the surfaces can be convex-concave, a meniscus (the outer surface is a convex surface while the inner surface is a concave), biconvex, or plano-convex so as to increase variability in light emitting patterns of the LED assembly. Furthermore, brightness and light-emitting efficiency are improved and optical design of the molded glass lens is simplified.

It is a further object of the present invention to provide a LED assembly with molded glass lens in which a frame arranged outside the molded glass lens can be circular, rectangular, polygonal, or asymmetrical so as to increase diversity of package of the LED component. Moreover, the structure of the LED component is simplified and cost of manufacturing as well as packaging is reduced.

It is a further object of the present invention to provide a LED assembly with molded glass lens in which filling holes are disposed on an outer frame of the molded glass lens or upper edge of a loading surface of a base so as to save cost of making a mold of conventional cover lens and further simplify packaging processes of the LED component.

It is a further object of the present invention to provide a LED assembly with molded glass lens in which a locking set is added between the base and the molded glass lens. For example, a slot is disposed on the outer frame of the molded glass lens while a corresponding projecting post is arranged on upper edge of the base. By assembling of the projecting post on the slot, the molded glass lens is covered and locked on the base. Furthermore, the binding strength of the LED assembly 1 before/after glue-filling is improved and the molded glass lens is easy to be located on the loading surface of the base.

### BRIEF DESCRIPTION OF THE DRAWINGS

FIG. 1 is a perspective view of an embodiment according to the present invention;

FIG. 2 is a side view of a LED assembly of the embodiment in FIG. 1;

FIG. 3 is a perspective view of the molded glass lens of the embodiment in FIG. 1;

FIG. 4 is a cross sectional view of the molded glass lens in FIG. 3;

FIG. 5 is an explosive view of the LED assembly of the embodiment in FIG. 1;

FIG. 6 is a cross sectional view of the embodiment in FIG. 1;

FIG. 7 is a perspective view of another embodiment according to the present invention;

FIG. 8 is a side view of a LED assembly of the embodiment in FIG. 7;

FIG. 9 is a cross sectional view of the molded glass lens in FIG. 7;

FIG. 10 is a perspective view of a further embodiment according to the present invention;

FIG. 11 is a side view of a LED assembly of the embodiment in FIG. 10;

FIG. 12 is a cross sectional view of the molded glass lens in FIG. 10;

FIG. 13 is a perspective view of a further embodiment according to the present invention;

FIG. 14 is a side view of a LED assembly of the embodiment in FIG. 13;

FIG. 15 is a cross sectional view of the molded glass lens in FIG. 13;

FIG. 16 is a perspective view of a further embodiment according to the present invention;

FIG. 17 is a side view of the embodiment in FIG. 16;

FIG. 18 is a cross sectional view of the molded glass lens in FIG. 16.

### DETAILED DESCRIPTION OF THE PREFERRED EMBODIMENT

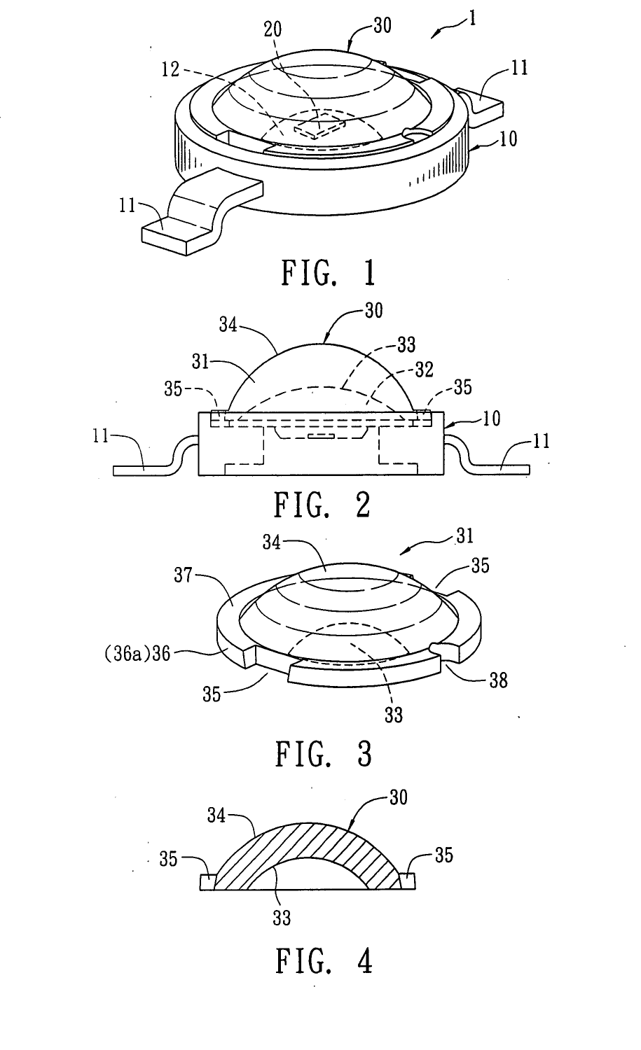

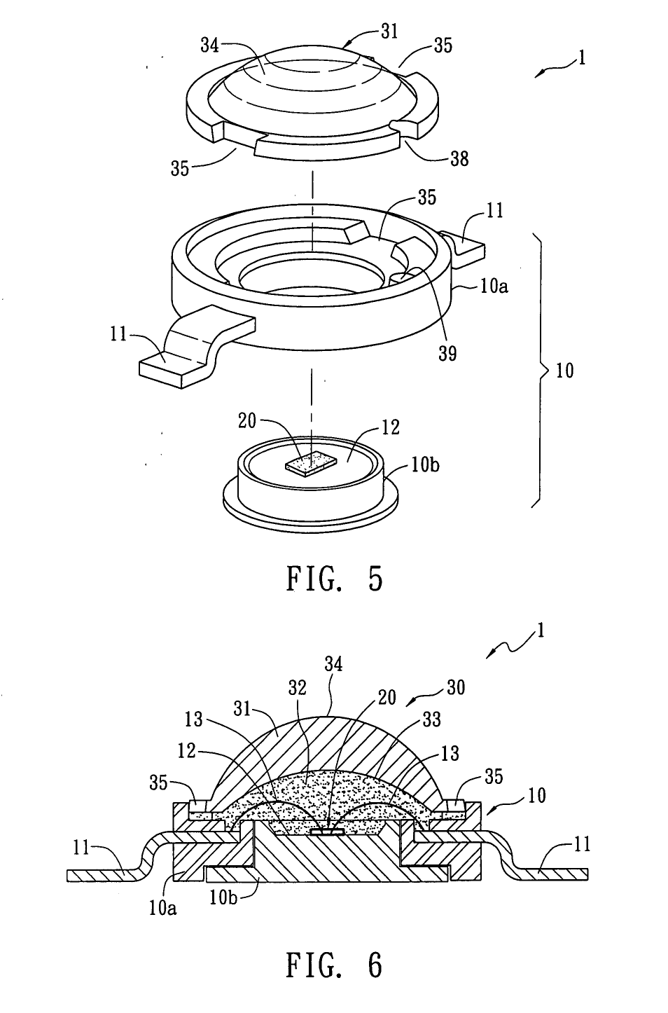

Refer to FIG. 1 & FIG. 2, a LED assembly 1 according to the present invention consists of a base 10, at least one LED chip 20 and a cover lens 30 made from molded glass. The base 10 includes at least one set of positive and negative electrodes 11 respectively connected with positive and negative power supplies, and a loading surface 12 for disposition of the LED chips 20. The least one LED chip 20 is arranged on the loading surface 12 of the base 10 and is electrically connected with the positive and negative electrodes 11 of the base 10 so as to make the LED chip 20 emit light. The base 10 is used for loading the LED chip 20 and enabling the LED chip 20 connected with an external power supply. The design of the base 10 can be modified. For example, refer to FIG. 5 & FIG. 6, the base 10 is an assembly formed by a plastic wire support 10a and a metal seat 10b. The pin-shaped positive and negative electrodes 11 of the external power supply are respectively arranged on two corresponding sides of the wire support 10a. Moreover, the loading surface is a concave disposed on top of the wire support 10a. During packaging processes, a conductor 13 is used to connect the LED chip 20 and the pin-shaped positive and negative electrodes 11 so as to form electrically connection. As to the conductor 13, there is no restriction on structure and connection way of the conductor 13. For example, the conductor 13 can be a conducting wire, as shown in FIG. 6 or a conducting strip (not shown in figure) that disposed between the positive and negative electrodes of the LED chip 20 and the positive and negative electrodes 11 of the base 10. Furthermore, the loading surface 12 can be a concave, as shown in FIG. 5 or a flat surface (not shown in figure).

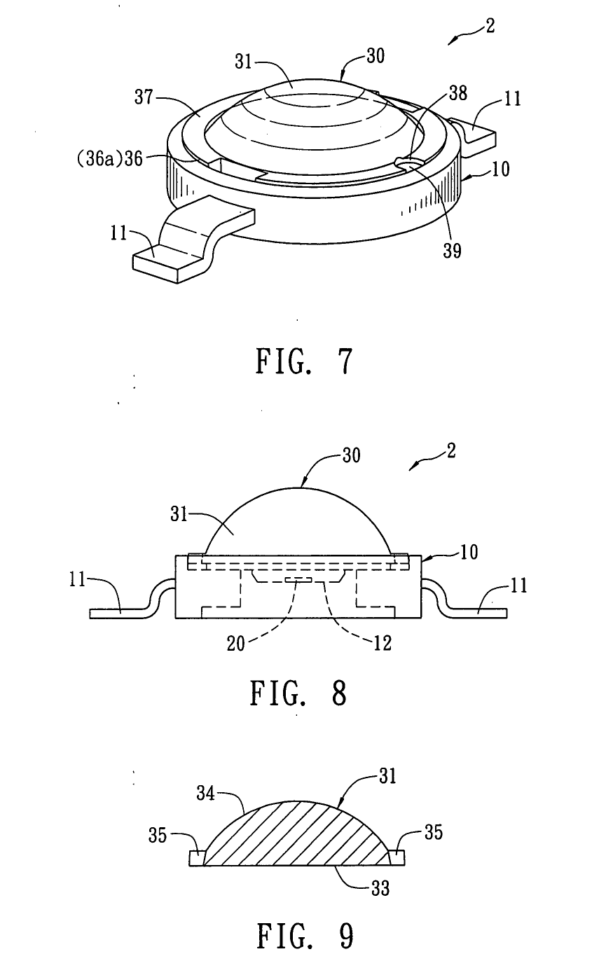

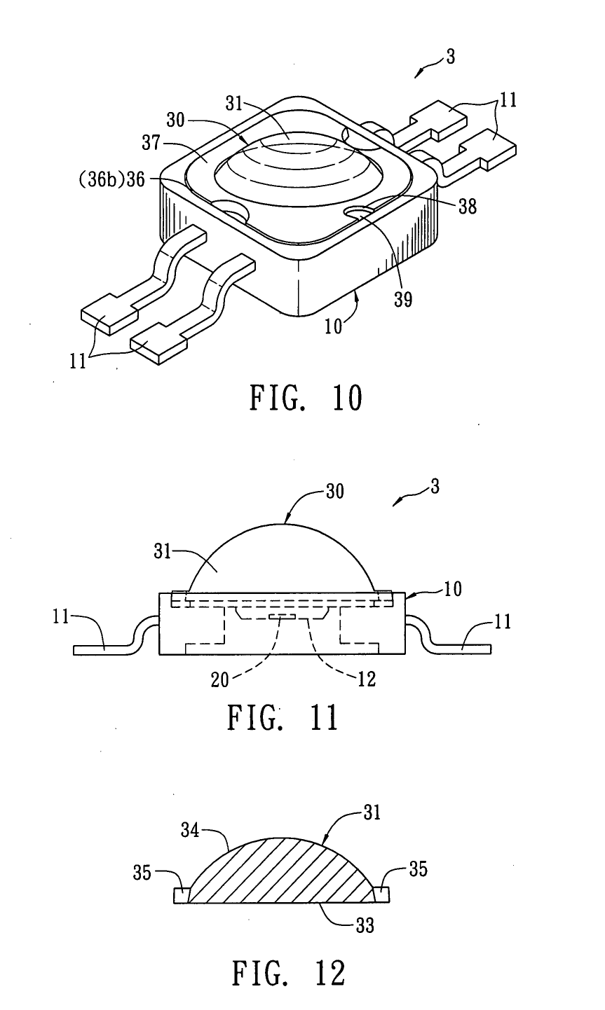

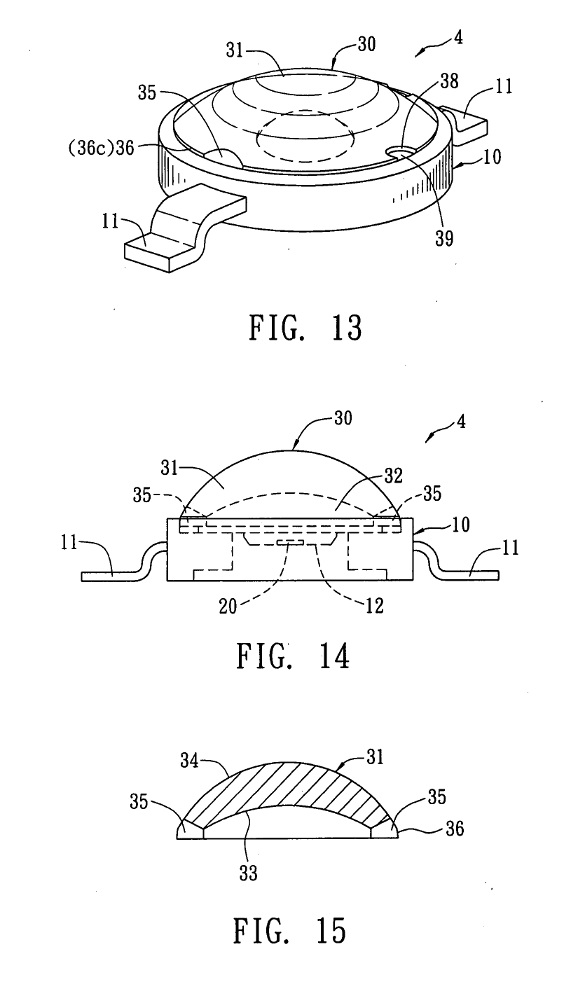

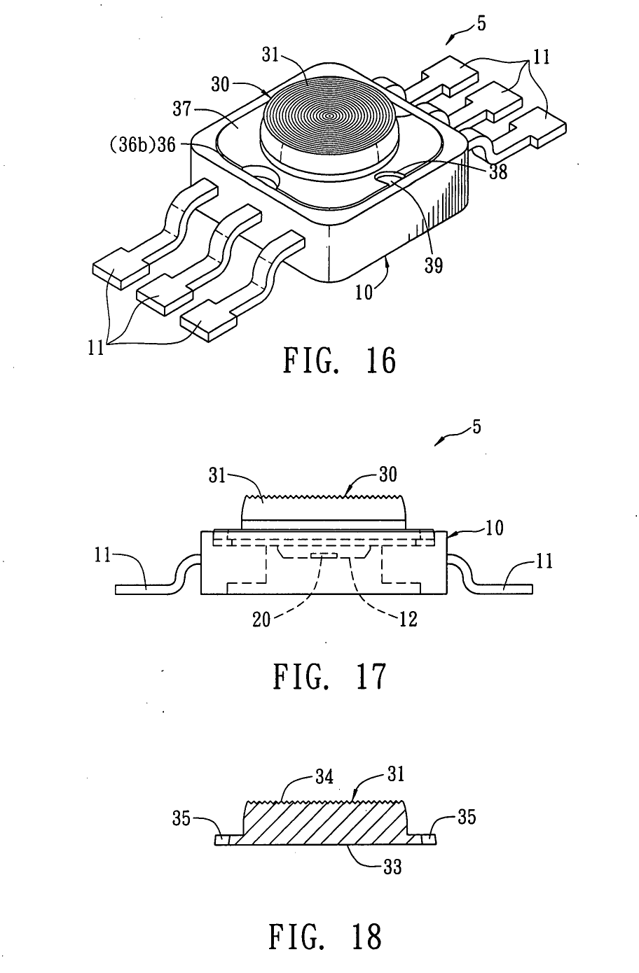

The number, color (red, green and blue) and disposition of the LED chip are not limited. One or a plurality of LED chip is disposed on the loading surface 12 so as to have single color or color mixing. As shown in figure, the pin-shaped positive and negative electrodes 11 include a set of a positive electrode and a negative electrode. There may several sets of positive and negative electrodes, depending on number or disposition of the LED chip 20. For example, a set of positive and negative electrodes 11 is used to control a LED chip 20, as the LED assembly 1, 2, 4 respectively shown in FIG. 1, FIG. 7, FIG. 13. Or two sets of positive and negative electrodes 11 are used to control two LED chips 20, as the LED assembly 3 shown in FIG. 10. Refer to the LED assembly 5 in FIG. 16, three sets of positive and negative electrodes 11 are used to control three LED chips 20.

Refer to FIG. 3 & FIG. 4, the present invention features on that: the cover lens 30 is composed of a molded glass lens 31 and a transparent resin layer 32. The molded glass lens 31 is made by high-precision pressing method. While packaging, the molded glass lens 31 is covered on the loading surface 12 of the base. Then the liquid transparent resin is filled into the space between an inner optical surface 33 of the molded glass lens 31 and the loading surface 12 through a preset filling hole 35 and is completely covered the LED chip 20. Thus after hardening, the liquid transparent resin becomes into a transparent resin layer 32 that is integrated with the molded glass lens 31 and the base. The softening temperature of the molded glass lens 31 ranges from 450 to 750 Celsius degrees so that the thermal resistance, weather resistance, discoloration resistance and mechanical strength of the LED assembly 1 are effectively improved. Moreover, the refraction and transmittance of the molded glass lens 31 are both higher than those of the conventional resin lens or plastic lens. Thus the brightness and light-emitting efficiency of the LED assembly are increased.

Refer to FIG. 3 & FIG. 4, surface types and different optical parameters of the inner and outer (upper/lower) optical surfaces 33, 34 of the molded glass lens 31 can be changed according to performance requirements of the LED assembly 1. Each surface can be concave, convex or planar. For example, refer to FIG. 4 & FIG. 15, the inner and outer optical surfaces 33, 34 are respectively both convex surfaces. Or as shown in FIG. 9 & FIG. 12, one is a concave while the other is planar. Or a thin lens as shown in FIG. 18, the inner and outer optical surfaces 33, 34 are respectively a coil surface and a flat surface. Therefore, the light emitting patterns of the LED assembly 1 are increased while optical design of the molded glass lens 31 is simplified. Moreover, the brightness and light emitting efficiency of the LED assembly 1 are improved.

Refer to FIG. 3, there is no limit on shape of a frame 36 of the molded glass lens 31 and design of the frame 36 can be modified according to requirements or package structure of the LED assembly 1. The frame 36 means out edge of the inner and outer optical surfaces 33, 34. A flat flange 37 is disposed between the inner, outer surfaces 33, 34 and the frame 36. Refer to FIG. 3, FIG. 4, FIG. 7 and FIG. 9, the frame 36a and the flange 37 are circular while in FIG. 10, FIG. 12, FIG. 16 and FIG. 18, the frame 36b and the flange 37 are rectangular. Or as shown in FIG. 13 & FIG. 15, only circular frame 36c exists without the flange 37. The frame 36 can be a polygonal or asymmetrical. An outer frame of the base 10 should be designed corresponding to the shape of the frame 36 or the flange 37. Thus the varieties of package structure of the LED assembly 1 are improved and the manufacturing processes of the molded glass lens 31 are simplified. Therefore, cost of the LED assembly is reduced.

There is no restriction on disposition positions of the filling holes 35 of the LED assembly 1. Refer from FIG. 1 to FIG. 6, the filling holes 35 can be arranged in pairs on two corresponding sides of the flange 37 of the molded glass lens 31 and/or on two corresponding sides of the outer frame of the base 10. Refer to FIG. 15, the filling holes 35 are arranged on two corresponding sides of the outer frame 36 of the molded glass lens 31. The filling holes 35 are formed easily and quickly and the filling of the transparent resin is more easily and directly. Therefore, the package of the LED assembly 1 is simplified.

Refer to FIG. 5, a locking set is added between the base 10 and the molded glass lens 31. For example, a slot 38 is disposed on the outer frame 36 of the molded glass lens 31 while a corresponding projecting post 39 is arranged on upper edge of the base 10. By assembling of the projecting post 39 on the slot 38, the molded glass lens 31 is locked on the base 10 while being covered on the loading surface 12 of the base 10 so as to prevent the molded glass lens 31 falling off from the base 10 caused by the pressure of filling glue. Moreover, the molded glass lens 31 is easy to be located and covered on the loading surface 12 of the base 10. The binding strength of the LED assembly 1 before/after packaging or glue-filling is improved.

What is claimed is:

1. A LED assembly with a molded glass lens comprising a base, at least one LED chip and a cover lens formed by the molded glass lens; wherein
the base having positive and negative electrodes respectively connected with connected with positive and negative power supplies so as to make the LED chip emit light, and a loading surface for disposition of the LED chip;
the LED chip arranged on the loading surface of the base and electrically connected with the positive and negative electrodes of the base to be driven for emitting light; and
the cover lens having a molded glass lens and a transparent resin layer while the molded glass lens is covered on the loading surface of the base and the transparent resin layer is filled between an inner optical surface of the molded glass lens and the loading surface, coating the LED chip so as to integrate the molded glass lens with the base;
thereby not only thermal resistance, weather resistance, discoloration resistance, and mechanical strength of the LED assembly are increased due to high softening temperature and high transmittance of the molded glass lens, but brightness and light-emitting efficiency of the LED assembly are also improved.

2. The LED assembly with a molded glass lens as claimed in claim 1, wherein an inner and an outer optical surfaces of the molded glass lens are a convex surface and a concave surface, both convex surfaces, a concave surface and a planar surface, or a coil surface and a planar surface.

3. The LED assembly with a molded glass lens as claimed in claim 1, wherein a circular frame and a circular flange are arranged on the molded glass lens.

4. The LED assembly with a molded glass lens as claimed in claim 1, wherein a rectangular frame and a rectangular flange are disposed on the molded glass lens.

5. The LED assembly with a molded glass lens as claimed in claim 1, wherein the molded glass lens is disposed with a circular frame.

6. The LED assembly with a molded glass lens as claimed in claim 1, wherein the molded glass lens is disposed with a polygonal frame.

7. The LED assembly with a molded glass lens as claimed in claim 1, wherein the molded glass lens is disposed with an asymmetrical frame.

8. The LED assembly with a molded glass lens as claimed in claim 1, wherein the LED assembly is preset with at least one filling hole.

9. The LED assembly with a molded glass lens as claimed in claim 8, wherein the at least one filling hole is disposed on the frame of the molded glass lens.

10. The LED assembly with a molded glass lens as claimed in claim 8, wherein the at least one filling hole is disposed on a frame of the base.

11. The LED assembly with a molded glass lens as claimed in claim 1, wherein a slot is disposed on a frame of the molded glass lens while a projecting post corresponding to the slot is arranged on upper edge of the base so as to make the molded glass lens cover and lock on the base.
